(19) United States
(12) Patent Application Publication
(10) Pub. No.: US 2009/0323170 A1
(43) Pub. Date: Dec. 31, 2009

(54) GROOVE ON COVER PLATE OR SUBSTRATE

(75) Inventor: Peng Cheng Lin, Cupertino, CA (US)

Correspondence Address: KNOBBE, MARTENS, OLSON & BEAR, LLP, 2040 MAIN STREET, FOURTEENTH FLOOR, IRVINE, CA, 92614, US

(73) Assignee: QUALCOMM MEMS Technologies, Inc., San Diego, CA (US)

(21) Appl. No.: 12/165,429

(22) Filed: Jun. 30, 2008

(51) Int. Cl. G02B 26/00; H01L 21/50; H01L 29/84

(52) U.S. Cl. 359/291; 438/51; 257/415; 257/E21.499; 257/E29.324

(57) ABSTRACT

An improved substrate or cover plate design with a groove for effective singulation of individual display apparatus. In one embodiment, the display apparatus comprises a prefabricated groove on an inside face of a substrate or cover plate to facilitate separation of a MEMS device from a plurality of MEMS devices formed a substrate. In some embodiments, the prefabricated grooves make breaking at pseudo scribe lines simple by thinning and weakening the substrate or cover plate at a scribe zone and act as an improved guide for breaking. Scribe cut relief preserves components, structural integrity, and produces a clean break without inducing excessive or unwanted stresses into the MEMS core and ensures no damage at the panel ledge for subsequent interconnect assembly.

### TECHNICAL FIELD

The present invention relates to display panels such as multi-layered LCD panels or Microelectromechanical systems (MEMS) display panels with an array of interference modulators, and the manufacturing methods thereof, and more particularly, to the shape and structure of a cover plate or substrate.

### DESCRIPTION OF RELATED TECHNOLOGY

Microelectromechanical systems (MEMS) include micro mechanical elements, actuators, and electronics. Micromechanical elements may be created using deposition, etching, and or other micromachining processes that etch away parts of substrates and/or deposited material layers or that add layers to form electrical and electromechanical devices. One type of MEMS device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal. In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

In the flat panel display manufacturing industry, a display such as a MEMS device may be manufactured by forming multiple display devices on a substrate and covering the display devices with a protective cover plate attached to the substrate, e.g. via a sealant or adhesive. As a result, the multiple display devices are packaged or sandwiched between the cover plate and substrate. Next, a conventional separation method is used to obtain individually packaged displays or panels from the multiple displays. One separation method is called “scribe and break”. Other separation methods include etching or sandblasting a cover plate or substrate followed by cutting or cracking.

Conventional scribe and break methods exhibit three steps in the following sequence: score, crack, and separation in normal direction to the glass plate. However, these methods have some unpredictability during the crack and separation steps, as a break away edge may contain additional cracks due to the inter dependence of the scribe and break process and the amount of force or pressure required in a separation method. First, the cutting tools may wear excessively from the force on the glass, or from a heavy load which is required for the separation step. As such, the cutting tools may fail to function properly, leading to unacceptably poor quality edges and more frequent replacement of the tools used to manufacture separation methods. Second, the force may propagate or induce excessive stress waves throughout the core of the display, weakening the display as it is being singulated. Third, the force can create a poor quality separation, by breaking, scratching, and/or shorting out other electronic components, especially the traces on the substrate under the sealant, which is referred to as “Kline out”. This poor quality separation often damages signal traces at the panel ledge, e.g., scratched traces or broken traces exhibiting line out issues on the display. This type of line out problem may be partially alleviated by increased preventive measures such as protective coating on signal traces and/or larger (more robust) signal traces.

Other separation method problems are related to breakage defects. First, separation methods can cause chipping or “butt wing” instead of producing a smooth and straight break. Second, separation methods often produce glass or other debris because there is not a clean break. These force and breakage defect problems can result in additional manufacturing time and expense such as closer inspections and more rework.

### SUMMARY

One embodiment is a method of manufacturing a microelectromechanical systems (MEMS) based display device, the method comprising providing a transparent substrate comprising a first MEMS device and a second MEMS device formed thereon, providing a cover plate, wherein at least one of the cover plate or the substrate includes a groove on an inside face of at least one of the cover plate or the substrate, orienting the cover plate or substrate so that the groove is located in an area between the first and second MEMS devices, joining the cover plate to the substrate to form a first package around the first MEMS device and a second package around the second MEMS device, applying a force between the first and second packages, wherein the force propagates a crack along the groove, and separating the first and second packages.

In another embodiment, there is a microelectromechanical systems (MEMS) based device, comprising a transparent substrate comprising a first MEMS device and a second MEMS device formed thereon, a cover plate joined to the substrate to form a first package around the first MEMS device and a second package around the second MEMS device, and a groove on an inside face of at least one of the cover plate or the substrate, wherein the groove is between the first and second MEMS devices, wherein an inside face of the cover plate faces an inside face of the substrate, wherein the groove on the inside face of at least one of the cover plate or the substrate reduces a strength of the cover plate or substrate to assist in separating the first and second MEMS devices.

In another embodiment, there is a microelectromechanical systems (MEMS) based device, comprising a transparent substrate supporting a first MEMS device and a second MEMS device formed thereon, a cover plate for covering the first and second MEMS devices, and means for weakening the substrate or the cover plate, wherein the weakening means is located in an area between the first and second MEMS devices, wherein the cover plate is coupled to the substrate to form a first package around the first MEMS device and a second package around the second MEMS device.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIGS. 5A and 5B illustrate one exemplary timing diagram for row and column signals that may be used to write a frame of display data to the 3×3 interferometric modulator display of FIG. 2.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIG. 8 is a side view illustrating one embodiment of packaged MEMS devices.

FIG. 9 is a top view illustrating one embodiment of packaged MEMS devices.

FIG. 10 is a perspective view illustrating one embodiment of packaged MEMS devices with grooves on an inside face of a cover plate.

FIG. 11 is a side view illustrating one embodiment of packaged MEMS devices with grooves on an inside face of a cover plate with a separation force being applied.

FIG. 12 is a side view illustrating one embodiment of packaged MEMS devices with grooves on an inside face of a substrate with a separation force being applied.

FIG. 13 is a side view illustrating one embodiment of packaged MEMS devices with grooves on inside faces of a cover plate and substrate with a separation force being applied.

FIG. 14 is a flow diagram illustrating one embodiment of manufacturing packaged MEMS devices with grooves on an inside face of a substrate or cover plate.

### DETAILED DESCRIPTION

The following detailed description is directed to certain specific embodiments. However, the teachings herein can be applied in a multitude of different ways. In this description, reference is made to the drawings wherein like parts are designated with like numerals throughout. The embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, notebook computer displays, tablet PC displays, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

One embodiment of the invention is a MEMS device having a groove on an inside and/or outside face (surface) of a substrate and/or a cover plate. In one embodiment, the groove weakens the cover plate and/or substrate by thinning a scribe zone so that multiple devices can be separated (singulated) with reduced force than might otherwise be needed, so that the reduced force can reduce or eliminate damage to each individual device. As a result, a lower separation force is required to separate devices from one another. Also, the groove reduces the amount of separation force that is propagated or induced throughout the display.

In another embodiment, the groove on the inside face of the cover plate and/or the substrate acts as a guide that provides a smoother and cleaner separation between devices than might result without the groove. As a result, during separation a smoother break is formed, which prevents chipping or excessive butt wing formation. Also, the cleaner break produces less glass or other debris which can weaken interconnect joints if not removed. Accordingly, in one embodiment, formation of the groove on the cover plate or the substrate provides scribe cut relief to the device in order to allow for an easier separation of multiple devices.

Although manufacturing of MEMS devices is given as an example where force or pressure can be applied to isolate (singulate) a packaged display, one skilled in the art would be aware that this method and/or apparatus can be applied to other manufactured displays, such as liquid crystal displays (LCD), light emitting diodes (LED), plasma display panels (PDP), and so on.

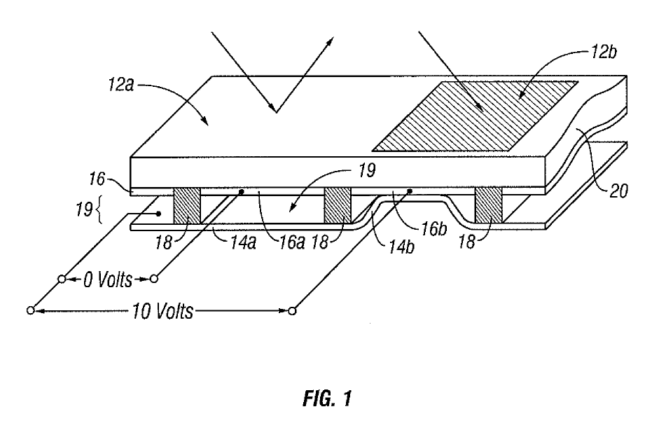

One interferometric modulator display embodiment comprising an interferometric MEMS display element is illustrated in FIG. 1. In these devices, the pixels are in either a bright or dark state. In the bright (“relaxed” or “open”) state, the display element reflects a large portion of incident visible light to a user. When in the dark (“actuated” or “closed”) state, the display element reflects little incident visible light to the user. Depending on the embodiment, the light reflectance properties of the “on” and “off” states may be reversed. MEMS pixels can be configured to reflect predominantly at selected colors, allowing for a color display in addition to black and white.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical gap with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise several fused layers, which can include an electrode layer, such as indium tin oxide (ITO), a partially reflective layer, such as chromium, and a transparent dielectric. The optical stack 16 is thus electrically conductive, partially transparent and partially reflective, and may be fabricated, for example, by depositing one or more of the above layers onto a transparent substrate 20. The partially reflective layer can be formed from a variety of materials that are partially reflective such as various metals, semiconductors, and dielectrics. The partially reflective layer can be formed of one or more layers of materials, and each of the layers can be formed of a single material or a combination of materials.

In some embodiments, the layers of the optical stack 16 are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) to form columns deposited on top of posts 18 and an intervening sacrificial material deposited between the posts 18. When the sacrificial material is etched away, the movable reflective layers 14a, 14b are separated from the optical stacks 16a, 16b by a defined gap 19. A highly conductive and reflective material such as aluminum may be used for the reflective layers 14, and these strips may form column electrodes in a display device. Note that FIG. 1 may not be to scale. In some embodiments, the spacing between posts 18 may be on the order of 10-100 um, while the gap 19 may be on the order of <1000 Angstroms.

With no applied voltage, the gap 19 remains between the movable reflective layer 14a and optical stack 16a, with the movable reflective layer 14a in a mechanically relaxed state, as illustrated by the pixel 12a in FIG. 1. However, when a potential (voltage) difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by actuated pixel 12b on the right in FIG. 1. The behavior is the same regardless of the polarity of the applied potential difference.

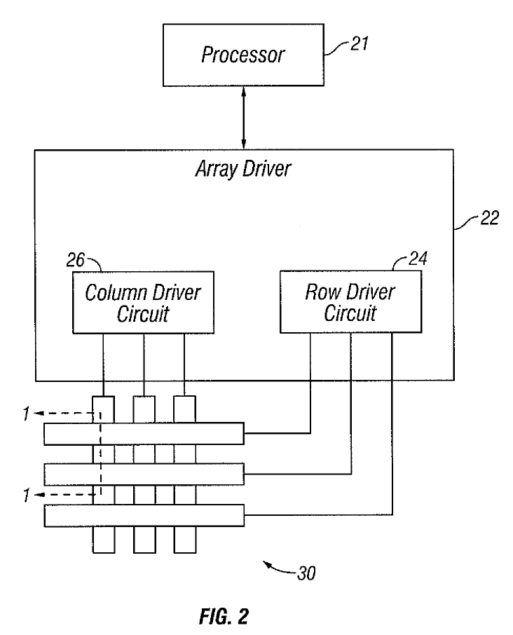

FIGS. 2 through 5 illustrate one exemplary process and system for using an array of interferometric modulators in a display application.

FIG. 2 is a system block diagram illustrating one embodiment of an electronic device that may incorporate interferometric modulators. The electronic device includes a processor 21 which may be any general purpose single- or multi-chip microprocessor such as an ARM®, Pentium®, 8051, MIPS®, Power PC®, or ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

In one embodiment, the processor 21 is also configured to communicate with an array driver 22. In one embodiment, the array driver 22 includes a row driver circuit 24 and a column driver circuit 26 that provide signals to a display array or panel 30. The cross section of the array illustrated in FIG. 1 is shown by the lines 1-1 in FIG. 2. Note that although FIG. 2 illustrates a 3×3 array of interferometric modulators for the sake of clarity, the display array 30 may contain a very large number of interferometric modulators, and may have a different number of interferometric modulators in rows than in columns (e.g., 300 pixels per row by 190 pixels per column).

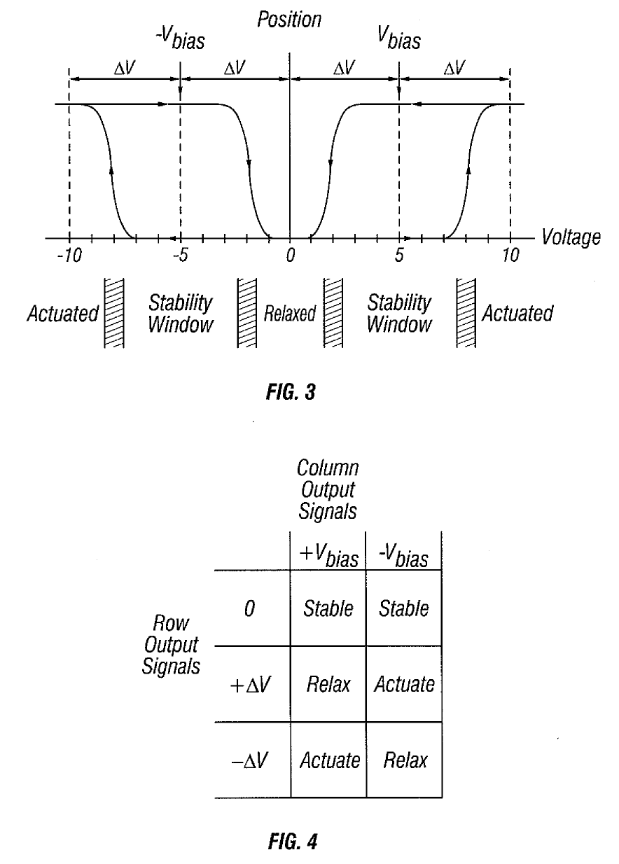

FIG. 3 is a diagram of movable mirror position versus applied voltage for one exemplary embodiment of an interferometric modulator of FIG. 1. For MEMS interferometric modulators, the row/column actuation protocol may take advantage of a hysteresis property of these devices as illustrated in FIG. 3. An interferometric modulator may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. There is thus a range of voltage, about 3 to 7 V in the example illustrated in FIG. 3, where there exists a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state or bias voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

As described further below, in typical applications, a frame of an image may be created by sending a set of data signals (each having a certain voltage level) across the set of column electrodes in accordance with the desired set of actuated pixels in the first row. A row pulse is then applied to a first row electrode, actuating the pixels corresponding to the set of data signals. The set of data signals is then changed to correspond to the desired set of actuated pixels in a second row. A pulse is then applied to the second row electrode, actuating the appropriate pixels in the second row in accordance with the data signals. The first row of pixels are unaffected by the second row pulse, and remain in the state they were set to during the first row pulse. This may be repeated for the entire series of rows in a sequential fashion to produce the frame. Generally, the frames are refreshed and/or updated with new image data by continually repeating this process at some desired number of frames per second. A wide variety of protocols for driving row and column electrodes of pixel arrays to produce image frames may be used.

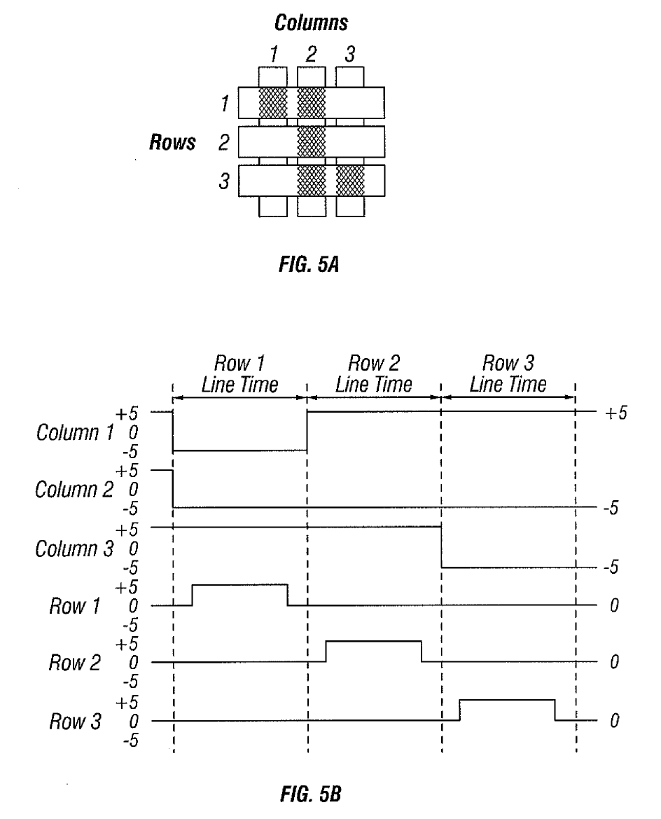

FIGS. 4 and 5 illustrate one possible actuation protocol for creating a display frame on the 3×3 array of FIG. 2, FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts respectively Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are initially at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. The same procedure can be employed for arrays of dozens or hundreds of rows and columns. The timing, sequence, and levels of voltages used to perform row and column actuation can be varied widely within the general principles outlined above, and the above example is exemplary only, and any actuation voltage method can be used with the systems and methods described herein.

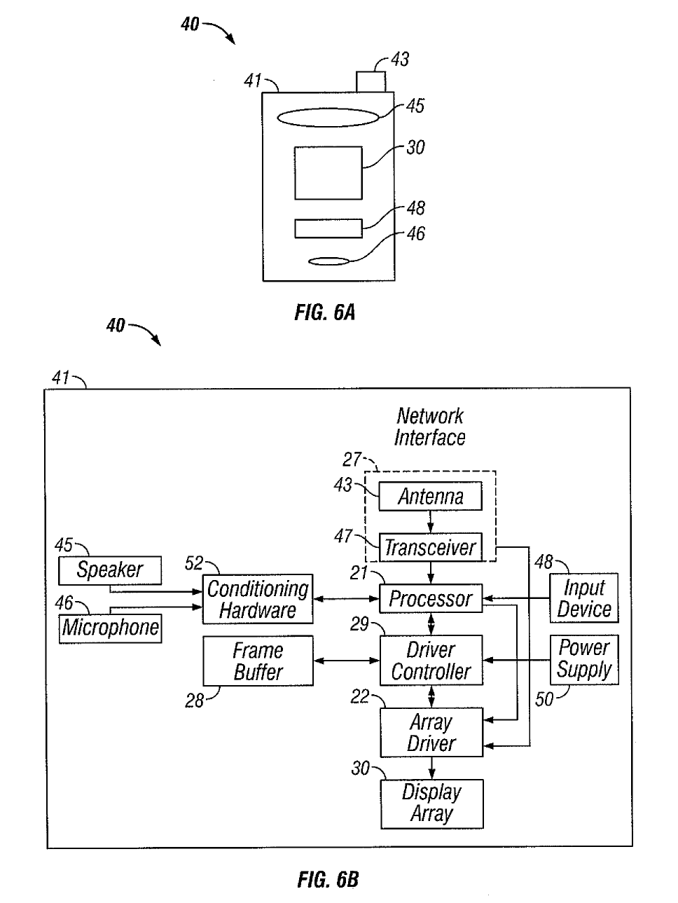

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 45, an input device 48, and a microphone 46. The housing 41 is generally formed from any of a variety of manufacturing processes, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g. filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one or more devices over a network. In one embodiment the network interface 27 may also have some processing capabilities to relieve requirements of the processor 21. The antenna 43 is any antenna for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS, W-CDMA, or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 generally includes amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In one embodiment, a driver controller 29 is integrated with the array driver 22. Such an embodiment is common in highly integrated systems such as cellular phones, watches, and other small area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a touch-sensitive screen, a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

Power supply 50 can include a variety of energy storage devices as are well known in the art. For example, in one embodiment, power supply 50 is a rechargeable battery, such as a nickel-cadmium battery or a lithium ion battery. In another embodiment, power supply 50 is a renewable energy source, a capacitor, or a solar cell, including a plastic solar cell, and solar-cell paint. In another embodiment, power supply 50 is configured to receive power from a wall outlet.

In some implementations control programmability resides, as described above, in a driver controller which can be located in several places in the electronic display system. In some cases control programmability resides in the array driver 22. The above-described optimization may be implemented in any number of hardware and/or software components and in various configurations.

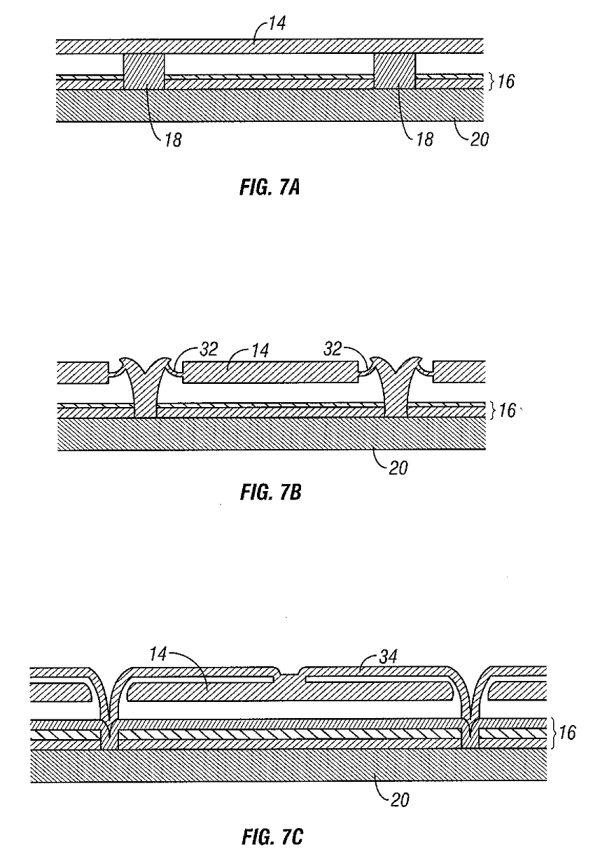

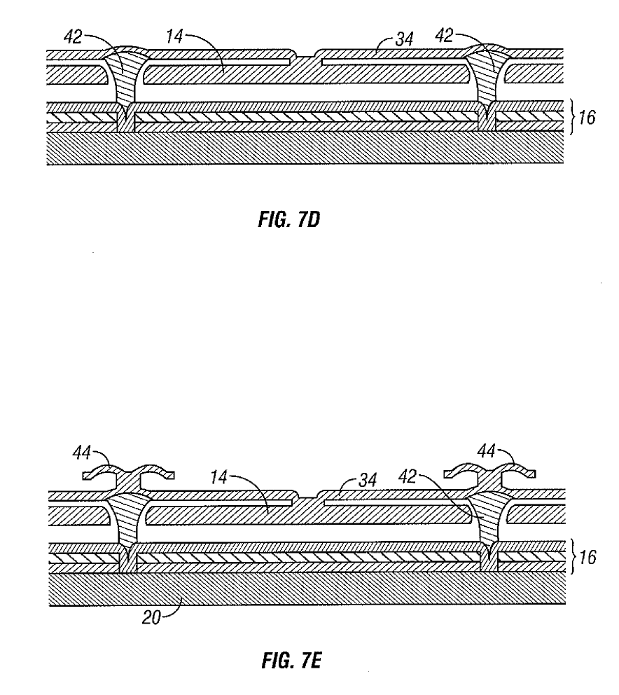

The details of the structure of interferometric modulators that operate in accordance with the principles set forth above may vary widely. For example, FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the moveable reflective layer 14 of each interferometric modulator is square or rectangular in shape and attached to supports at the corners only, on tethers 32. In FIG. 7C, the moveable reflective layer 14 is square or rectangular in shape and suspended from a deformable layer 34, which may comprise a flexible metal. The deformable layer 34 connects, directly or indirectly, to the substrate 20 around the perimeter of the deformable layer 34. These connections are herein referred to as support posts. The embodiment illustrated in FIG. 7D has support post plugs 42 upon which the deformable layer 34 rests. The movable reflective layer 14 remains suspended over the gap, as in FIGS. 7A-7C, but the deformable layer 34 does not form the support posts by filling holes between the deformable layer 34 and the optical stack 16. Rather, the support posts are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7, the interferometric modulators function as direct-view devices, in which images are viewed from the front side of the transparent substrate 20, the side opposite to that upon which the modulator is arranged. In these embodiments, the reflective layer 14 optically shields the portions of the interferometric modulator on the side of the reflective layer opposite the substrate 20, including the deformable layer 34. This allows the shielded areas to be configured and operated upon without negatively affecting the image quality. For example, such shielding allows the bus structure 44 in FIG. 7E, which provides the ability to separate the optical properties of the modulator from the electromechanical properties of the modulator, such as addressing and the movements that result from that addressing. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

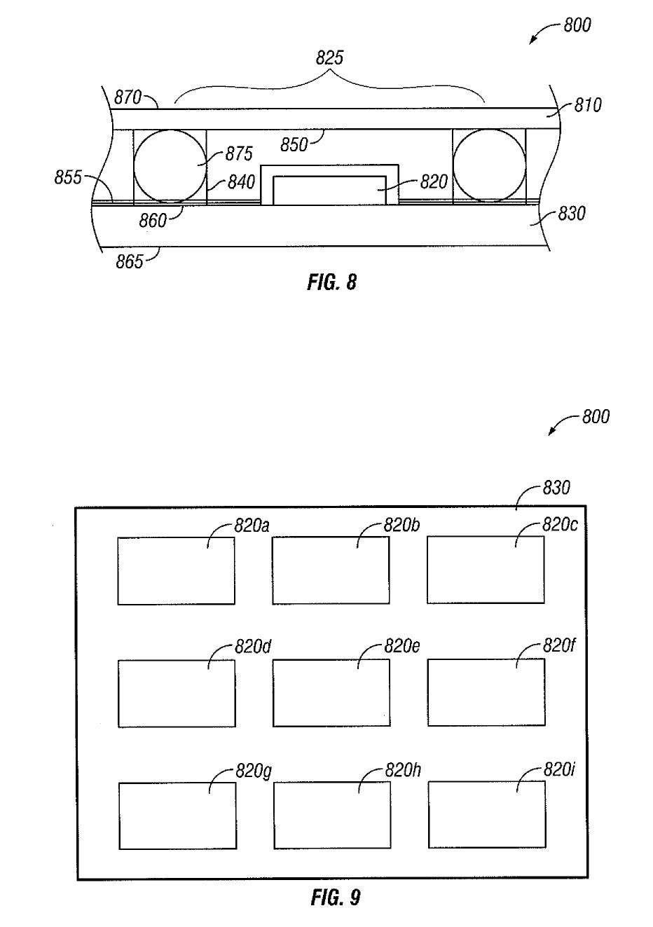

Referring now to FIG. 8, a side cross-sectional view of packaged MEMS devices 800 is illustrated. As discussed in FIGS. 1-7, one type of MEMS device 820 can be an interferometric modulator device that comprises an interferometric modulator array, which selectively transmits, absorbs, and/or reflects light using the principles of optical interference. In FIG. 8, the packaged MEMS devices 800 are shown before a manufacturing separation method is used to separate an individual MEMS package 825 from other of the MEMS devices 800.

In FIG. 8, the MEMS device 820 can be formed on a transparent substrate 830 and covered by a cover plate 810. As a result, the MEMS device 820 is packaged or sandwiched between the cover plate 810 and substrate 830 to form the package 825, where an inside face 850 of the cover plate 810 and inside face 855 of the substrate 830 are attached to a sealant 840 with a spacer 875. The substrate 830 often contains sensitive leads or traces 860 thereon that pass under the sealant 840 to communicate data between the MEMS device 820 and connectors or other electronics located outside of the package 825.

The cover plate 810 may be flat as shown in FIG. 8, or the cover plate 810 may instead have a curve or recess for fitting closely around the MEMS device 820. Materials for the cover plate 810 include glass, plastic, or metal. Materials for the substrate 830 include transparent materials. In one embodiment, before separation into one packaged MEMS device, the substrate 830 and cover plate 810 may be a “plate” larger than about 14″×16″, where the plate includes a number of MEMS devices 820.

In another embodiment (not shown), the MEMS devices comprise a display that communicates with a processor to process image data, where the processor communicates with a memory device for storing data. This embodiment may also include a driver circuit configured to send at least one signal to the display and a controller configured to send at least a portion of the image data to the driver circuit. This embodiment may also include an image source module configured to send the image data to the processor, where the image source module includes at least one of a receiver, transceiver, and transmitter, and an input device configured to receive input data and to communicate the input data to the processor.

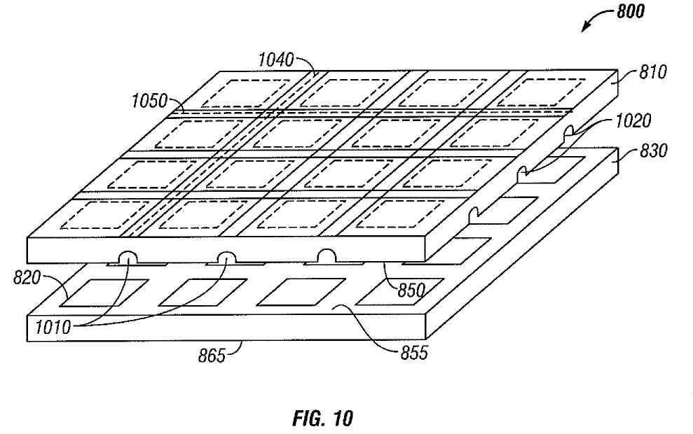

FIG. 9 is a top view of FIG. 8, illustrating one embodiment of the packaged MEMS devices 800 as shown in FIG. 8 arranged on a plate, before singulation. The cover plate 810 (not shown in this figure) has been removed for illustrative purposes, so that the array of MEMS devices 820a-i on the substrate 830 can be seen. Alternatively, the cover plate 810 in this embodiment is clear. Rather than manufacturing each MEMS device 820 separately, the MEMS device 820 is often fabricated as one of many MEMS devices 820 on a relatively large substrate “plate” along with many other MEMS devices 820, and after the MEMS devices 820 are completed, they are separated from one another. For example, FIG. 9 illustrates a manufactured plate having 3 rows and 3 columns of MEMS devices 820a-820i, but virtually any number of MEMS devices 820 may be included on the plate, depending on the size of the plate, the size of the MEMS devices 820, and the required separation between the MEMS devices 820 on the plate. As is discussed further below, one advantage of the embodiments described herein is that the MEMS devices 820 can be more closely arranged on the plate, potentially allowing for a larger number of MEMS devices 820 for a given size of plate. In one embodiment, a prefabricated groove (described below with respect to FIG. 10) is formed before the MEMS device 820 is fabricated onto the substrate 830.

FIG. 10 is an exploded perspective view illustrating one embodiment of a plate of packaged MEMS devices 825 before singulation. As illustrated, there are vertical grooves 1010 and horizontal grooves 1020 on the inside face 850 of the cover plate 810. The grooves 1010 or 1020 can be continuous or discrete. If the grooves are discrete, the grooves 1010 or 1020 can circumscribe around the entire perimeter of the MEMS device 820, or less than an entire perimeter of the MEMS device 820. The grooves 1010 or 1020 can be formed by one or more of sandblasting, etching, waterjetting, sawing, laser scribing, or grinding based on the properties of the cover plate 810 or substrate 830.

The grooves 1010 or 1020 can reduce a strength of the cover plate 810 and/or substrate 830 at the scribe zone to assist in separating a first MEMS device package 825 from a second MEMS device package 825. Thus, grooves 1010 or 1020 provide one means for weakening the substrate 830 or the cover plate 810. This assistance in separation can be from the reduced force required to separate the devices or the reduced force propagated onto the display during singulation. This groove can act as a guide for crack propagation, which is propagated by applying force to the grooves 1010 and/or 1020.

FIG. 10 also illustrates pseudo vertical scribe lines 1040 and pseudo horizontal scribe lines 1050 on the outside face 870 of the cover plate 810. These pseudo scribe lines 1040 and 1050 are located between the individually packaged MEMS devices 825 and are indicated by scribe alignment marks positioned at opposite ends of the cover plate 810 or MEMS devices 820. Scribe lines are used in the scribe and break method to mark and facilitate breaking the cover plate 810 or substrate 830.

As discussed above, scribe cut relief includes the prefabricated grooves 1010 or 1020 on the inside face 850 or 855 of the substrate 830 and/or cover plate 810. In one embodiment, grooves 1010 or 1020 weaken the cover plate and/or substrate at the scribe zones so that breakage is warranted, requiring less force to separate panels and propagating less stress throughout the display. In another embodiment, the grooves 1010 or 1020 on the inside face 850 or 855 of the cover plate 810 or the substrate 830 act as an improved guide for a smoother and cleaner separation without chips, cracks, and butt wings with less glass debris as compared with a cover plate without grooves.

Multiple shapes and sizes for the grooves 1010 or 1020 are possible. In one embodiment, the depth of the grooves 1010 or 1020 can be between 100 to 300 microns, where the depth/thickness in FIG. 8 could be measured as the vertical distance from the inside face 850 or 855 to the outside face 870 or 865 of the cover plate 810 or substrate 830, respectively. In another embodiment, the depth of the grooves 1010 or 1020 is between 1/7 and ½ a thickness of the cover plate 810 or the substrate. In another embodiment, the width of the groove can be between 100 to 300 microns, where the width in FIG. 8 would be a horizontal distance. As a result, the depth and width of the groove 1010 or 1020 may be the same or different distances. The depth of the groove can be different percentages of the depth/thickness of the cover plate, including: 5%, 10%, 15%, 20%, 25%, 30%, 35%, 40%, 45%, 50%, 55%, 60%, 65%, 70%, 75%, 80%, 85%, 90%, or 95%.

The grooves 1010 or 1020 can be conveniently created on the cover glass 810 during the manufacturing process used to create a recess for the MEMS devices 825. The grooves 1010 or 1020 can weaken the induced stress waves propagated into the MEMS core. The grooves 1010 or 1020 allow individual packages or panels to be separated without extra loading force. The grooves 1010 or 1020 prevent butt wing formation on an edge of the cover glass 810 or substrate 830, which would expose a Chip of Glass (COG) zone and Flex on Glass (FOG) zone. Flex can be a flex printed circuit (FPC) board.

COG and FOG are attachment methods or interconnect schemes. COG refers to the placement, alignment, and bonding of an integrated circuit (IC), such as a display driver IC, at its corresponding footprint on the substrate for electrical connection and for the circuit to process signals for the display core. FOG refers to the placement, alignment, and bonding of one end of the FPC on the substrate at an area adjacent to the COG. FOG sends signals and power to the display via COG.

The grooves 1010 or 1020 reduce or eliminate scratched or broken traces at a panel ledge. The grooves 1010 or 1020 minimize panel singulation yield loss and quality issue due to unpredictable cover glass cracking and chipping, and butt wing adjacent to the ledge. In addition, the grooves 1010 or 1020 reduce the cost of quality control, inspection, and rework. The grooves 1010 or 1020 are transparent to existing backend flow during singulation and thus can easily be incorporated into process development and volume production environments. Also, the grooves 1010 or 1020 require no real estate increase for the individual MEMS package 825.

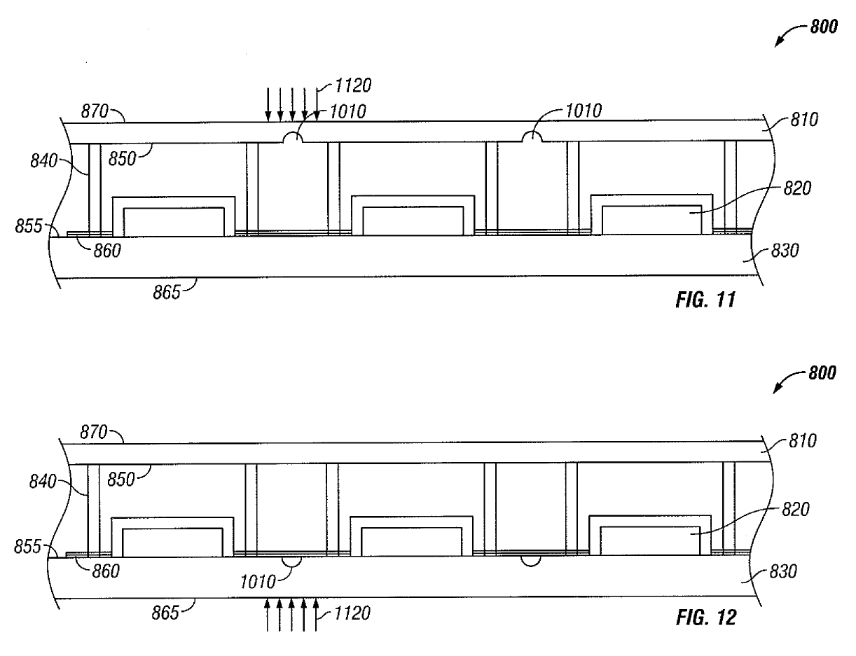

FIG. 11 illustrates a side view of FIG. 10, illustrating one embodiment of a plate of packaged MEMS devices 800 with the grooves 1010 or 1020 on the inside face 850 of the cover plate 810. FIG. 11 illustrates a force or separation apparatus 1120 being applied to the cover plate 810. A separation method often applies inward force on the cover plate 810 or the substrate 830 in order to separate each individual MEMS package 825 into individual panels or packages. In one embodiment, a separation method 1120 is a scribe and break method. Like FIG. 10, the grooves 1010 or 1020 provide scribe cut relief.

FIG. 11 illustrates the grooves 1010 as semi-circular and protruding into the cover plate 810. However, as discussed above, other shapes and sizes for the grooves 1010 or 1020 are possible. In one embodiment, the depth of the grooves 1010 or 1020 can be between 100 to 300 microns. In another embodiment, the depth of the grooves 1010 or 1020 is between ⅓ and ½ a thickness of the cover plate 810. In another embodiment, the width of the groove can be between 100 to 300 microns. As a result, the depth and width of the groove 1010 or 1020 may be the same or different dimensions.

FIG. 12 is a side view illustrating one embodiment of a plate of packaged MEMS devices 800. As illustrated, the grooves 1010 are located on the inside face 855 of a substrate 830, instead of the inside face 850 of the cover plate 810. In FIG. 12, the separation force 1120 is being applied to the substrate 830.

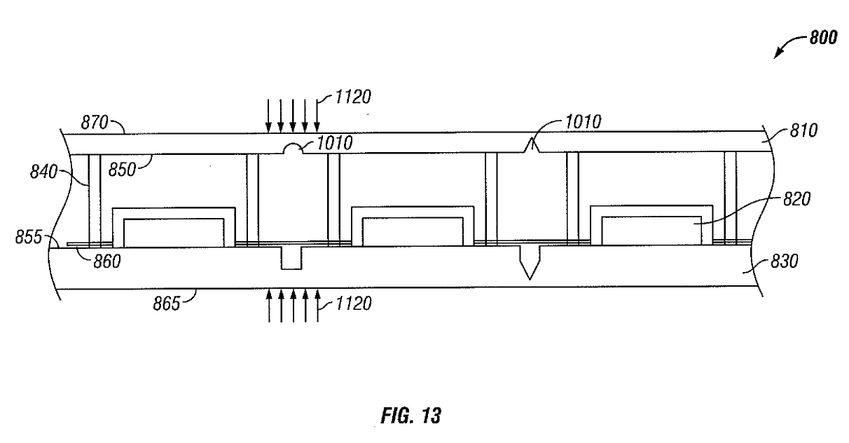

FIG. 13 is a side view illustrating one embodiment of a plate of packaged MEMS devices 800. As illustrated, the grooves 1010 are on the inside faces 850 and 855 of both the cover plate 810 and the substrate 830. The separation method 1120 is applied to the cover plate 810 and the substrate 830. In this figure, the grooves 1010 are shown in different sizes, shapes, and depths to facilitate singulation. The grooves 1010 or 1020 can be many shapes, such as a straight line, circular, or rectangular. The grooves 1010 or 1020 may also be referred to as a penetration, fenestration, slot, hole, microhollow, trough, exterior window, opening, piercing, etc.

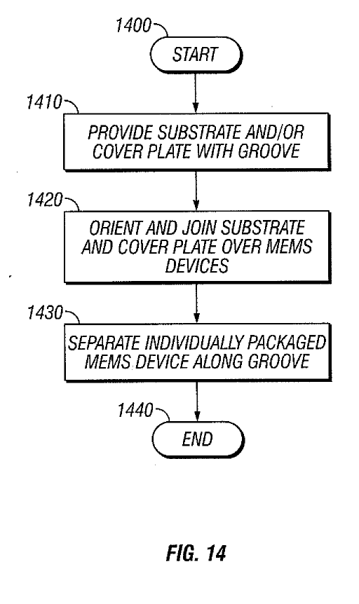

FIG. 14 is a flow diagram illustrating one embodiment of manufacturing packaged MEMS devices with the grooves 1010 or 1020 on the inside face 850 or 855 of the substrate 830 or the cover plate 810. In one embodiment, this method takes place in ambient conditions; other embodiments operate in military, commercial, industrial, and extended temperature ranges.

The manufacturing process starts at step 1400. Next, at step 1410 a machine or semi-automated process creates the prefabricated grooves 1010 in the substrate 830 and/or the cover plate 810. Proceeding to step 1420, a machine or semi-automated process orients the cover plate 810 over the MEMS devices 820 formed on the substrate 830, so that the grooves are located in an area between each individual MEMS package 825. The cover plate 810 and substrate 830 can then be joined or fabricated together using a sealant 840. Subsequently, step 1430 separates the individually packaged MEMS device 825 along the grooves 1010 or 1020 using force or a separation method 1120, where the grooves 1010 or 1020 weaken the substrate 830 or cover plate 810 containing the grooves 1010 or 1020 or acts as an additional guide for breaking. As discussed above, scribe cut relief includes the grooves 1010 or 1020 which require less force, propagate less stress on the display, and produce less chipping/debris.

The steps of a method or algorithm described in connection with the embodiments disclosed herein may be embodied directly in a computer or electronic storage, in hardware, in a software module executed by a processor, or in a combination thereof. A software module may reside in a computer storage such as in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a mobile station. In the alternative, the processor and the storage medium may reside as discrete components in a mobile station.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method of manufacturing a microelectromechanical systems (MEMS) based display device, the method comprising:
providing a transparent substrate comprising a first MEMS device and a second MEMS device formed thereon;
providing a cover plate, wherein at least one of the cover plate or the substrate includes a groove on an inside face;
orienting the cover plate or substrate so that the groove is located in an area between the first and second MEMS devices;
joining the cover plate to the substrate to form a first package around the first MEMS device and a second package around the second MEMS device;
applying a force between the first and second packages, wherein the force propagates a crack along the groove; and
separating the first and second packages.

2. The method of claim 1, wherein the groove weakens the cover plate or substrate so that less force is required to separate the first and second packages.

3. The method of claim 1, wherein the groove acts as a guide for the crack.

4. The method of claim 1, wherein separating the first and second packages comprises scribing the substrate or the cover plate.

5. The method of claim 1, wherein a depth of the groove is between 100 to 300 microns.

6. The method of claim 5, wherein a width of the groove is between 100 to 300 microns.

7. The method of claim 1, wherein a depth of the groove is between ⅓ to ½ a thickness of the cover plate.

8. The method of claim 1, wherein a width of the groove is the same as a depth of the groove.

9. The method of claim 1, further comprising forming the groove by one or more of sandblasting, etching, waterjetting, sawing, laser scribing, or grinding.

10. The method of claim 1, wherein the cover plate comprises a recess on a surface facing the transparent substrate.

11. The method of claim 1, wherein the groove circumscribes the first or second MEMS device.

12. The method of claim 11, wherein the groove forms a circular or rectangular shape around the MEMS device.

13. The method of claim 1, wherein the groove surrounds less than an entire perimeter around the MEMS device.

14. The method of claim 1, wherein the substrate comprises glass or plastic.

15. The method of claim 1, wherein the cover plate comprises glass, plastic, or metal.

16. The method of claim 1, wherein the method takes place in ambient conditions.

17. A microelectromechanical systems (MEMS) based device, comprising:
a transparent substrate comprising a first MEMS device and a second MEMS device formed thereon;
a cover plate joined to the substrate to form a first package around the first MEMS device and a second package around the second MEMS device; and
a groove on an inside face of at least one of the cover plate or the substrate, wherein the groove is between the first and second MEMS devices, wherein an inside face of the cover plate faces an inside face of the substrate, wherein the groove on the inside face of at least one of the cover plate or the substrate reduces a strength of the cover plate or substrate.

18. The device of claim 17, wherein the groove weakens the cover plate or substrate so that less force is required to separate the first and second packages.

19. The device of claim 17, further comprising a crack propagated by applying force along the groove, wherein the groove acts as a guide for the crack.

20. The device of claim 17, wherein the substrate comprises a size of about 14″×16″ or greater.

21. The device of claim 17, wherein the cover plate is larger than about 14″×16″ and includes multiple grooves oriented between adjacent MEMS devices.

22. The device of claim 17, wherein the separating the first and second MEMS devices comprises scribing and breaking the substrate and the cover plate, wherein the groove provides scribe cut relief.

23. The device of claim 17, further comprising:
a display;
a processor that is configured to communicate with the display, the processor being configured to process image data; and
a memory device that is configured to communicate with the processor.

24. The device of claim 23, further comprising a driver circuit configured to send at least one signal to the display.

25. The device of claim 24, further comprising a controller configured to send at least a portion of the image data to the driver circuit.

26. The device of claim 23, further comprising an image source module configured to send the image data to the processor.

27. The device of claim 26, wherein the image source module comprises at least one of a receiver, transceiver, and transmitter.

28. The device of claim 23, further comprising an input device configured to receive input data and to communicate the input data to the processor.

29. A microelectromechanical systems (MEMS) based device, comprising:
a transparent substrate supporting a first MEMS device and a second MEMS device formed thereon;
a cover plate for covering the first and second MEMS devices; and
means for weakening the substrate or the cover plate, wherein the weakening means is located in an area between the first and second MEMS devices, wherein the cover plate is coupled to the substrate to form a first package around the first MEMS device and a second package around the second MEMS device.

30. The device of claim 29, wherein the weakening reduces the force required to separate the first and second packages.

31. The device of claim 29, wherein the weakening means acts as a guide for a crack propagated along the weakening means.

32. The device of claim 29, wherein the first and second MEMS devices comprise interferometric modulator arrays.
